(19) United States
(12) Patent Application Publication
(10) Pub. No.: US 2024/0213273 A1
(43) Pub. Date: Jun. 27, 2024

(54) DISPLAY SUBSTRATE, METHOD FOR DETECTING CRACK, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Qing GONG, Beijing (CN); Xu LU, Beijing (CN); Yuanqi HUANG, Beijing (CN); Li XIAO, Beijing (CN)

(21) Appl. No.: 17/913,810

(22) PCT Filed: Oct. 25, 2021
(86) PCT No.: PCT/CN2021/126126

§ 371 Date: Sep. 22, 2022

(30) Foreign Application Priority Data
Jan. 15, 2021 (CN) 202110055900.6

(51) Int. Cl. H01L 27/12

(52) U.S. Cl. CPC H01L 27/1244

(57) ABSTRACT

The present application relates to the technical field of display. Disclosed are a crack detection method, a display substrate, and a display device. The display substrate is provided with a crack detection circuit that can achieve a crack detection function. Moreover, the crack detection circuit of the display substrate is provided with two different lines, and therefore two crack detection solutions can be supported. The display substrate is used for the display device.

### CROSS-REFERENCE TO RELATED APPLICATION

This application is a U.S. national stage of international application No. PCT/CN2021/126126, filed on Oct. 25, 2021, which claims priority to Chinese Patent Application No. 202110055900.6 filed on Jan. 15, 2021 and entitled “CRACK DETECTION METHOD, DISPLAY SUBSTRATE, AND DISPLAY DEVICE.” and the disclosures of which are herein incorporated by reference in their entireties.

### TECHNICAL FIELD

The present disclosure relates to the field of display technologies, and in particular, relates to a method for detecting a crack, a display substrate, and a display device.

### BACKGROUND

With the advancement of display technologies, display panels have been widely used.

### SUMMARY

Embodiments of the present disclosure provide a method for detecting a crack, a display substrate, and a display device. The technical solutions are as follows.

According to some embodiments of the present disclosure, a display substrate is provided. The display substrate includes: a base substrate, a plurality of data lines, and a crack detection circuit that are disposed on the base substrate: wherein the base substrate includes a display region and a peripheral region surrounding the display region, at least part of the plurality of data lines are disposed on the display region,
and the crack detection circuit includes a first line and a second line: wherein two ends of the first line are connected to a controller, one end of the second line is connected to the controller, and the other end of the second line is connected to at least one of the plurality of data lines.

In some embodiments, the crack detection circuit includes a first trace, a second trace, and a third trace, wherein two ends of the first trace and two ends of the second trace are connected to the controller, and the first trace is connected to the second trace via the third trace:
the at least one of the plurality of data lines includes at least one first data line and at least one second data line, wherein the first trace is connected to the at least one first data line, and the second trace is connected to the at least one second data line;
wherein a first connection portion between the first trace and the third trace is proximal to one end of the first trace, and a second connection portion between the first trace and the at least one first data line is proximal to the other end of the first trace; and a third connection portion between the second trace and the third trace is proximal to one end of the second trace, and a fourth connection portion between the second trace and the at least one second data line is proximal to the other end of the second trace;
the first line successively passes through the other end of the first trace, the first connection portion, the third trace, the third connection portion, and the other end of the second trace; and
the crack detection circuit includes two second lines, wherein one of the two second lines successively passes through the one end of the first trace, the first connection portion, and the second connection portion, and the other of the two second lines successively passes through the one end of the second trace, the third connection portion, and the fourth connection portion.

In some embodiments, the display substrate further includes: the controller disposed on the peripheral region of the base substrate: wherein the at least one of the plurality of data lines extends from the display region to the peripheral region and is connected to the controller; and the controller is configured to:
in a first detection phase, detect a resistance in the first line, and determining, based on the resistance, whether a crack is present in a position where the first line passes through in the display substrate; and/or
in a second detection phase, provide a data signal to the at least one of the plurality of data lines via the second line.

In some embodiments, the display substrate further includes: the controller disposed on the peripheral region of the base substrate: wherein the at least one of the plurality of data lines extends from the display region to the peripheral region and is connected to the controller; and the controller is configured to:
in the first detection phase, control the one end of the first trace and the one end of the second trace to be in a high resistance state, detect a resistance in the first line from the other end of the first trace and the other end of the second trace, and determine, based on the resistance, whether a crack is present in a position where the first line passes through in the display substrate.

In some embodiments, the display substrate further includes: the controller disposed on the peripheral region of the base substrate: wherein the at least one of the plurality of data lines extends from the display region to the peripheral region and is connected to the controller; and the controller is configured to:
in the second detection phase, control the other end of the first trace and the other end of the second trace to be in a high resistance state, and provide a data signal to the one end of the first trace and the one end of the second trace.

In some embodiments, the first trace passes through a first side and a second side of the display region, the second trace passes through the second side and a third side of the display region, and the third trace is disposed on a fourth side of the display region, wherein the first side is opposite to the third side, and the second side is opposite to the fourth side.

In some embodiments, an orthogonal projection of the first trace on a reference plane is overlapped with an orthogonal projection of the second trace on the reference plane, wherein the reference plane is intersected with a direction from the second side to the fourth side.

In some embodiments, the display substrate further includes a control line, a first switch assembly corresponding to the first data line, and a second switch assembly corresponding to the second data line: wherein
the control line, the first switch assembly, and the second switch assembly are disposed on the base substrate, the first data line is connected to the first trace through the first switch assembly, and the second data line is connected to the second trace through the second switch assembly; and the control line is connected to both the first switch assembly and the second switch assembly, and two ends of the control line are connected to the controller; and the controller is configured to:
in the first detection phase, provide a first signal to the control line, wherein the first signal is configured to control a switch assembly connected to the control line to be in a closed state;
in the second detection phase, provide a second signal to the control line, wherein the second signal is configured to control the switch assembly connected to the control line to be in an open state.

In some embodiments, the plurality of data lines further include at least one third data line other than the at least one of the plurality of data lines, wherein at least part of the at least one third data line is disposed on the display region; and
the display substrate further includes a third switch assembly corresponding to the third data line, wherein the third switch assembly is disposed on the base substrate, the third data line is connected to the third trace through the corresponding third switch assembly, and the control line is further connected to the third switch assembly.

In some embodiments, each of the first switch assembly, the second switch assembly, and the third switch assembly is a thin-film transistor.

In some embodiments, the controller is a driver integrated circuit IC.

According to some embodiments of the present disclosure, a method for detecting a crack is provided. The method for detecting the crack is applicable to the display substrate according to the above embodiments, and the method includes:
providing a base substrate;
forming a plurality of data lines and a crack detection circuit on the base substrate;
wherein the base substrate includes a display region and a peripheral region surrounding the display region, at least part of the plurality of data lines are disposed on the display region, and the crack detection circuit includes a first line and a second line: wherein two ends of the first line are connected to a controller, one end of the second line is connected to the controller, and the other end of the second line is connected to at least one of the plurality of data lines.

In some embodiments, upon providing the base substrate, the method further includes: disposing the controller on the base substrate.

In some embodiments, the crack detection circuit includes a first trace, a second trace, and a third trace, wherein two ends of the first trace and two ends of the second trace are connected to the controller, and the first trace is connected to the second trace via the third trace:
the at least one of the plurality of data lines includes at least one first data line and at least one second data line, wherein the first trace is connected to the at least one first data line, and the second trace is connected to the at least one second data line;
a first connection portion between the first trace and the third trace is proximal to one end of the first trace, and a second connection portion between the first trace and the at least one first data line is proximal to the other end of the first trace: a third connection portion between the second trace and the third trace is proximal to one end of the second trace, and a fourth connection portion between the second trace and the at least one second data line is proximal to the other end of the second trace;
the first line successively passes through the other end of the first trace, the first connection portion, the third trace, the third connection portion, and the other end of the second trace; and
the crack detection circuit includes two second lines, wherein one of the two second lines successively passes through the one end of the first trace, the first connection portion, and the second connection portion, and the other of the two second lines successively passes through the one end of the second trace, the third connection portion, and the fourth connection portion: and upon providing the base substrate, the method further includes:
forming a control line, a first switch assembly corresponding to the first data line, and a second switch assembly corresponding to the second data line on the base substrate;
wherein the first data line is connected to the first trace through the first switch assembly, and the second data line is connected to the second trace through the second switch assembly: and the control line is connected to both the first switch assembly and the second switch assembly, and two ends of the control line are connected to the controller.

In some embodiments, the plurality of data lines further includes at least one third data line other than the at least one of the plurality of data lines, and upon providing the base substrate, the method further includes:
forming a third switch assembly corresponding to the third data line on the base substrate;
wherein the third data line is connected to the third trace through the corresponding third switch assembly, and the control line is further connected to the third switch assembly.

According to some embodiments of the present disclosure, a method for detecting a crack is provided. The method is applicable to the controller connected to the crack detection circuit in the display substrate according to above embodiments, and the method includes:
at least one of detection methods in a first detection phase and a second detection phase; wherein
a detection method in the first detection phase includes: detecting a resistance in the first line, and determining, based on the resistance, whether a crack is present in a position where the first line passes through in the display substrate; and
a detection method in the second detection phase includes: providing a data signal to the at least one of the plurality of data lines via the second line.

In some embodiments, the crack detection circuit includes a first trace, a second trace, and a third trace:
the detection method in the first detection phase further includes: controlling one end of the first trace and one end of the second trace to be in a high resistance state;
the detection method in the second detection phase further includes: controlling the other end of the first trace and the other end of the second trace to be in the high resistance state;
detecting the resistance in the first line includes: detecting a resistance in the first line from the other end of the first trace and the other end of the second trace; and
providing the data signal to the at least one of the plurality of data lines via the second line includes: providing a data signal to the one end of the first trace and the one end of the second trace.

In some embodiments, the display substrate includes a control line, at least one first switch assembly, and at least one second switch assembly:

the detection method in the first detection phase further includes: providing a first signal to the control line, wherein the first signal is configured to control a switch assembly connected to the control line to be in a closed state; and
the detection method in the second detection phase further includes: providing a second signal to the control line, wherein the second signal is configured to control the switch assembly connected to the control line to be in an open state.

According to some embodiments of the present disclosure, an apparatus for detecting a crack is provided. The apparatus is applicable to the controller connected to the crack detection circuit in the display substrate according to above embodiments, and the apparatus includes: at least one of a detecting module and a first signal providing module; wherein
the detecting module is configured to, in a first detection phase, detect a resistance in the first line, and determine, based on the resistance, whether a crack is present in a position where the first line passes through in the display substrate;
the first signal providing module is configured to, in a second detection phase, provide a data signal to the at least one of the plurality of data lines via the second line.

In some embodiments, in the case that the apparatus for detecting the crack includes the detecting module, the apparatus for detecting the crack further includes: a first control module, configured to control one end of the first trace and one end of the second trace to be in a high resistance state in the first detection phase; and the detecting module is configured to detect a resistance in the first line from the other end of the first trace and the other end of the second trace; and
in the case that the apparatus for detecting the crack includes the first signal providing module, the apparatus for detecting the crack further includes: a second control module, configured to control the other end of the first trace and the other end of the second trace to be in the high resistance state in the second detection phase: the first signal providing module is configured to provide a data signal to the one end of the first trace and the one end of the second trace.

In some embodiments, in the case that the apparatus for detecting the crack includes the detecting module, the apparatus for detecting the crack further includes: a second signal providing module, configured to provide a first signal to the control line in the first detection phase, wherein the first signal is configured to control a switch assembly connected to the control line to be in a closed state; and
in the case that the apparatus for detecting the crack includes the first signal providing module, the apparatus for detecting the crack further includes: a third signal providing module, configured to provide a second signal to the control line in the second detection phase, wherein the second signal is configured to control the switch assembly connected to the control line to be in an open state.

According to some embodiments of the present disclosure, a chip is provided. The chip is applicable to a controller and includes a programmable logic circuit and/or program instructions, wherein the chip, when running, is caused to perform the method for detecting the crack according to above embodiments.

According to some embodiments of the present disclosure, a computer-readable storage medium is provided in the embodiments of the present disclosure. The computer-readable storage medium stores instructions, wherein the computer-readable storage medium, when running on a processing assembly, causes the processing assembly to perform the processes performed by the controller or the chip in above embodiments.

According to some embodiments of the present disclosure, a computer program product including instructions is provided. The computer program product, when running on a computer, causes the computer to perform the method for detecting the crack according to above embodiments.

According to some embodiments of the present disclosure, a display device is provided. The display device includes the display substrate according to above embodiments.

### BRIEF DESCRIPTION OF THE DRAWINGS

For clearer descriptions of the technical solutions in the embodiments of the present disclosure, the following briefly introduces the accompanying drawings required for describing the embodiments. Apparently, the accompanying drawings in the following description show merely some embodiments of the present disclosure, and a person of ordinary skill in the art still derives other drawings from these accompanying drawings without creative efforts.

FIG. 1 is a schematic structural diagram of a display substrate according to some embodiments of the present disclosure:

FIG. 2 is a schematic structural diagram of another display substrate according to some embodiments of the present disclosure:

FIG. 3 is a schematic structural diagram of another display substrate according to some embodiments of the present disclosure:

FIG. 4 is a schematic structural diagram of a crack detection circuit according to some embodiments of the present disclosure:

FIG. 5 is a schematic structural diagram of another crack detection circuit according to some embodiments of the present disclosure:

FIG. 6 is a schematic structural diagram of another display substrate according to some embodiments of the present disclosure:

FIG. 7 is a schematic structural diagram of another display substrate according to some embodiments of the present disclosure:

FIG. 8 is a flowchart of a method for preparing the base substrate according to some embodiments of the present disclosure:

FIG. 9 is a flowchart of another method for preparing the base substrate according to some embodiments of the present disclosure:

FIG. 10 is a flowchart of a method for detecting a crack according to some embodiments of the present disclosure:

FIG. 11 is a flowchart of another method for detecting a crack according to some embodiments of the present disclosure; and

FIG. 12 is a schematic structural diagram of an apparatus for detecting a crack according to some embodiments of the present disclosure.

### DETAILED DESCRIPTION

For clearer descriptions of the objectives, technical solutions, and advantages in the present disclosure, the embodiments of the present disclosure are described in detail hereinafter in combination with the accompanying drawings.

A display substrate in the display panel includes a pixel unit and a drive circuit, and the pixel unit is driven by the drive circuit to achieve displaying.

However, the display substrate is prone to cracks, such that the drive circuit in the display substrate is damaged, and a display effect of the display panel is affected.

FIG. 1 is a schematic structural diagram of a display substrate according to some embodiments of the present disclosure. Referring to FIG. 1, the display substrate includes a base substrate 01, a plurality of data lines 02 and a crack detection circuit that are disposed on the base substrate 01. The base substrate includes a display region F and a peripheral region N surrounding the display region, and at least part of the plurality of data lines are disposed on the display region F.

In some embodiments, the crack detection circuit includes a first line x and a second line y. Two ends of the first line x are connected to a controller, one end of the second line y is connected to the controller, and the other end of the second line is connected to at least one of the plurality of data lines 02.

In some embodiments, as shown in FIG. 1, a center region of the base substrate 01 is the display region F, and a surrounding region of the display region F is the peripheral region N. The position of the crack detection circuit on the base substrate 01 is not limited in the embodiments of the present disclosure, and FIG. 1 is shown by taking the first line x and the second line y in the crack detection circuit being disposed within the peripheral region N of the base substrate 01 as an example. In some embodiments, the first line x and the second line y are further disposed within the display region F of the base substrate 01. In some embodiments, parts of the first line x and the second line y are disposed within the display region F of the base substrate 01, and parts of the first line x and the second line y are disposed within the peripheral region N of the base substrate 01. FIG. 1 shows three data lines, a part of the data lines are disposed within the display region F, and the other part of the data lines extend to the peripheral region N. Two ends of the first line x and one end of the second line y are connected to the controller, and the other end of the second line y is connected to ends, extending to the peripheral region N, of the three data lines.

It is understood that, FIG. 1 only shows three data lines connected to the second line y, and the plurality of data lines in the display substrate further include other data lines than the three data lines although FIG. 1 does not show the other data lines. In some embodiments, a number of the data lines connected to the second line y in the display substrate is not equal to three. In some embodiments, the number is two, four, seven, ten, or the like, which is not limited in the embodiments of the present disclosure.

It is noted that, FIG. 1 does not show the specific trace of the crack detection circuit, and the first line x and the second line y are merely two paths of the crack detection circuit. The first line x and the second line y are two independent traces of the crack detection circuit. In some embodiments, the first line x and the second line y share a part of the trace, which is not limited in the embodiments of the present disclosure.

It is further noted that, the crack detection circuit includes at least one first line x and at least one second line y, and numbers of the first line x and the second line y are not limited in the embodiments of the present disclosure.

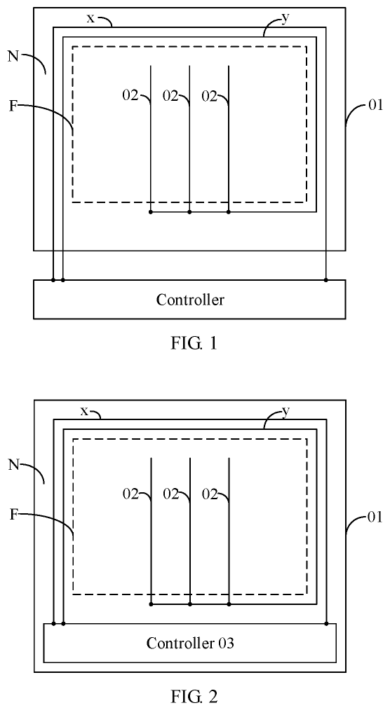

The above embodiments are described by taking the display substrate not including the controller as an example. In some embodiments, the display substrate further includes the controller. In some embodiments, FIG. 2 is a schematic structural diagram of another display substrate according to some embodiments of the present disclosure. As shown in FIG. 2, the display substrate further includes the controller 03. The controller 03 is disposed on the base substrate 01.

In some embodiments, the controller 03 is configured to have a function in at least one of a first detection phase and a second detection phase.

In some embodiments, the function of the controller in the first detection phase includes detecting a resistance in the first line x (for example, detecting a resistance between two ends of the first line x), and determining, based on the resistance, whether a crack is present in a position where the first line x passes through in the display substrate.

The first line x is conducted in the case that no crack is present in the position where the first line x passes through in the display substrate, and the resistance in the first line x is less than a resistance threshold. The crack in the position where the first line x passes through in the display substrate causes a break of the first line x, and the resistance in the first line x is greater than the resistance threshold. Therefore, where the resistance in the first line x detected by the controller 03 is greater than the resistance threshold, it is determined that the crack is present in the position where the first line x passes through in the display substrate. Where the resistance in the first line x detected by the controller 03 is less than or equal to the resistance threshold, it is determined that no crack is present in the position where the first line x passes through in the display substrate.

In some embodiments, the function of the controller in the second detection phase includes providing a data signal to the at least one of the plurality of data lines 02 connected to the second line y via the second line y.

In some embodiments, assuming that a pixel unit connected to the data line does not emit light in response to receiving a data signal at a high voltage, and emits light in response to not receiving the data signal at the high voltage, in the second detection phase, the controller 03 provides the data signal at the high voltage (such as the data signal at 7V) to an end, connected to the controller 03, of the second line y. Where no crack is present in the position where the second line y passes through in the display substrate, the signal at the high voltage is transmitted to the data line connected to the second line y through the second line y. Thus, the column of the pixel unit connected to the data line does not emit light, and the column of the pixel unit is a dark line. Where the crack is present in the position where the second line y passes through in the display substrate, the signal at the high voltage is not transmitted to the data line connected to the second line y through the second line y. Thus, the column of the pixel unit connected to the data line emits light, and the column of the pixel unit is a bright line. Thus, the user determines whether the crack is present in the position where the second line y passes through by viewing whether the column of the pixel unit connected to the data line connected to the second line y in the display region is the bright line.

It is noted that, whether the pixel unit connected to the data line emits light in response to receiving the data signal at the high voltage is related to the structure of the pixel unit. The pixel unit connected to the data line emits light in response to receiving the data signal at the high voltage, and does not emit light in response to not receiving the data signal at the high voltage, which is not limited in the embodiments of the present disclosure. Assuming that the pixel unit connected to the data line emits light in response to receiving the data signal at the high voltage, and does not emit light in response to not receiving the data signal at the high voltage, then the column of the pixel unit connected to the data line is the bright line in the case that no crack is present in the position where the second line y passes through in the display substrate, and the column of the pixel unit connected to the data line is the dark line in the case that the crack is present in the position where the second line y passes through in the display substrate. In this case, the user determines whether the crack is present in the position where the second line y passes through by viewing whether the column of the pixel unit connected to the data line connected to the second line y in the display region is the dark line.

Above crack detection circuits are implemented in various manners, and the crack detection circuits are described by taking one of the implementations as an example.

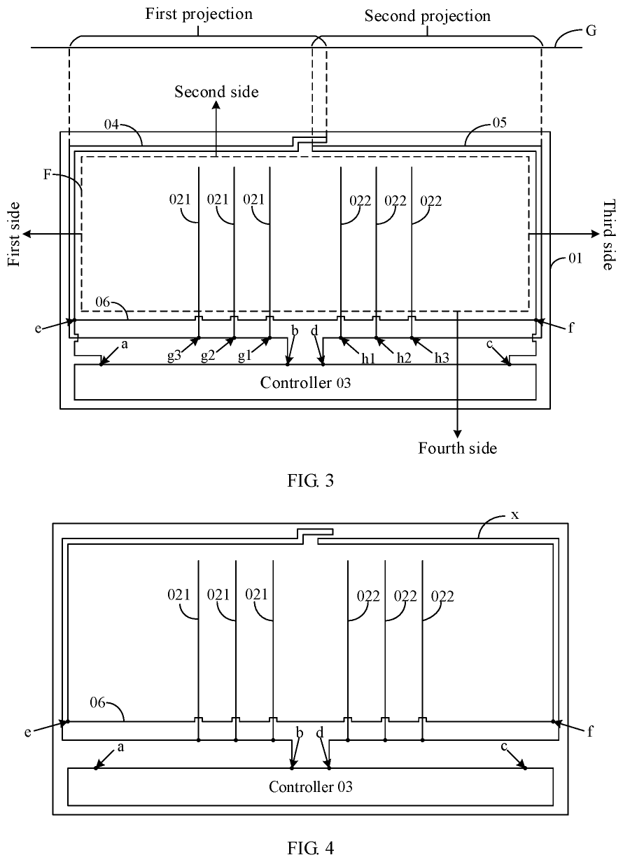

In some embodiments, FIG. 3 is a schematic structural diagram of another display substrate according to some embodiments of the present disclosure. As shown in FIG. 3, on the basis of the display substrate shown in FIG. 2, the crack detection circuit in the display substrate includes: a first trace 04, a second trace 05, and a third trace 06. Two ends of the first trace 04 and two ends of the second trace 05 are connected to the controller 03, and the first trace 04 are connected to the second trace 05 via the third trace 06.

The at least one of the plurality of data lines 02 connected to the second line y includes at least one first data line 021 and at least one second data line 022, the first trace 04 is connected to the at least one first data line 021, and the second trace 05 is connected to the at least one second data line 022.

A first connection portion e between the first trace 04 and the third trace 06 is proximal to one end a of the first trace 04, and a second connection portion between the first trace 04 and the at least one first data line 021 is proximal to the other end b of the first trace 04. A third connection portion f between the second trace 05 and the third trace 06 is proximal to one end c of the second trace 05, and a fourth connection portion between the second trace 05 and the at least one second data line 022 is proximal to the other end d of the second trace 05.

In some embodiments, FIG. 3 shows three first data lines 021 and three second data lines 022, and second connection portions between the three first data lines 021 and the first trace 04 include: a connection portion g1, a connection portion g2, and a connection portion g3. The connection portion g1, the connection portion g2, and the connection portion g3 are proximal to the other end b of the first trace 04. Fourth connection portions between the three second data lines 022 and the second trace 05 include: a connection portion h1, a connection portion h2, and a connection portion h3, and the connection portion h1, the connection portion h2, and the connection portion h3 are proximal to the other end d of the second trace 05.

In some embodiments, the crack detection circuit includes the first line x, and FIG. 4 is a schematic diagram of a first line x in a crack detection circuit. As shown in FIG. 4, the first line x successively passes through the other end b of the first trace, the first connection portion e, the third trace 06, the third connection portion f, and the other end d of the second trace.

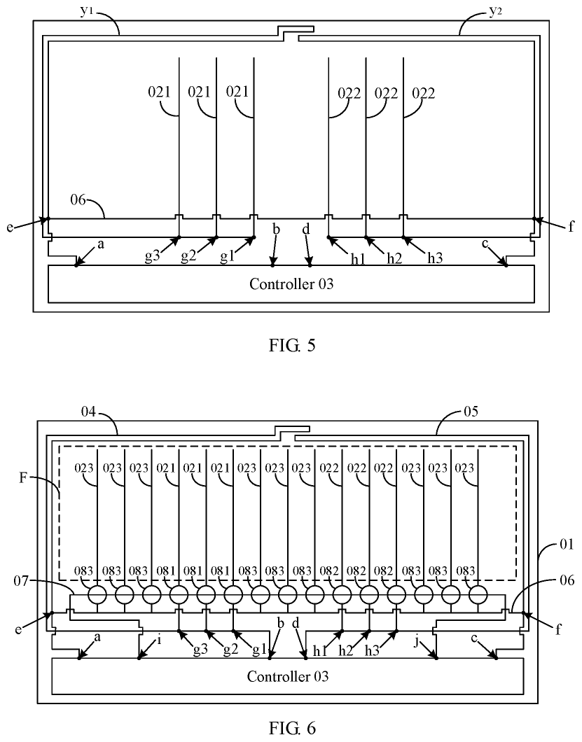

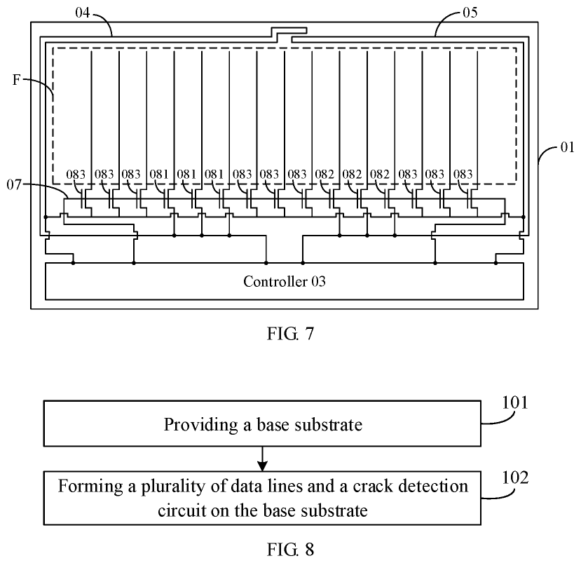

In some embodiments, the crack detection circuit includes two second lines, and FIG. 5 is a schematic diagram of a second line y in a crack detection circuit. As shown in FIG. 5, one of the two second lines y, successively passes through the one end a of the first trace, the first connection portion e, and the second connection portion (including connection portion g1, the connection portion g2, and the connection portion g3), and the other of the two second lines y2 successively passes through the one end c of the second trace, the third connection portion f, and the fourth connection portion (including the connection portion h1, the connection portion h2, and the connection portion h3).

The manner of disposing the trace in the crack detection circuit in FIG. 3 ensures that the crack detection circuit simultaneously includes the first line and the second line. In addition, the first line and the second line share a part of the trace, which optimizes the trace layout of the crack detection circuit and reduce the trace length.

In addition, referring to FIG. 5, positions where the second line y1 and second line y2 in the crack detection circuit pass through the display substrate are different, and the first data line 021 is connected to the second line y1, and the second data line 022 is connected to the second line y2. Thus, the controller detects, in the second detection phase, whether the crack is present in the position where the first data line 021 passes through in the display substrate by providing the data signal to the first data line 021 connected to the second line y1 through the second line y1. In some embodiments, the controller further detects, in the second detection phase, whether the crack is present in the position where the second data line 022 passes through in the display substrate by providing the data signal to the second data line 022 connected to the second line y2 through the second line y2. In this way, whether the crack is present in various positions in the display substrate is detected, so as to determine the position of the crack in the display substrate.

In some embodiments, assuming that the pixel unit connected to the data line does not emit light in response to receiving the data signal at the high voltage, and emits light in response to not receiving the data signal at the high voltage, then in the second detection phase, the controller 03 provides the data signal to the first data line 021 through the second line y1, and provides the data signal to the second data line 022 through the second line y2. In this case, where the column of the pixel unit connected to the first data line 021 emits light and the column of the pixel unit connected to the second data line 022 does not emit light, the crack is present in the position where the second line y1 connected to the first data line 021 in the display substrate passes through, and no crack is present in the position where the second line y2 connected to the second data line 022 in the display substrate passes through.

In the case that the crack detection circuit is shown in FIG. 3, the controller 03 is configured to: in the first detection phase, control the one end a of the first trace 04 and the one end c of the second trace 05 to be in a high resistance state, detect a resistance in the first line x from the other end b of the first trace 04 and the other end d of the second trace 05, and determine, based on the resistance, whether the crack is present in the position where the first line passes through in the display substrate. The high resistance state refers to an output state, a terminal in the high resistance state has no effect on the connected circuit. That is, the high resistance state is referred to as a break state.

In some embodiments, the controller 03 provides a square wave signal at a high resistance to the one end a of the first trace 04 and the one end c of the second trace 05 in the first detection phase, such that the one end a of the first trace 04 and the one end c of the second trace 05 are in the high resistance state. Furthermore, the controller 03 detects a resistance between the other end b of the first trace 04 and the other end d of the second trace 05, and the resistance is the resistance in the first line x. In the case that the one end a of the first trace 04 and the one end c of the second trace 05 are in the high resistance state, the one end a of the first trace 04 and the first connection portion e are break, and the one end c of the second trace 05 and the third connection portion f are broken. Referring to FIG. 4, in this case, only the first line x is conducted in the crack detection circuit, such that the crack detection is performed through the first line x.

In the crack detection circuit shown in FIG. 3, the controller 03 is configured to, in the second detection phase, control the other end b of the first trace 04 and the other end d of the second trace 05 to be in the high resistance state, and provide a data signal to the one end a of the first trace 04 and the one end c of the second trace 05.

In some embodiments, the controller 03 provides a square wave signal to the other end b of the first trace 04 and the other end d of the second trace 05, such that the other end b of the first trace 04 and the other end d of the second trace 05 are in the high resistance state; and provides the data signal to the one end a of the first trace 04 and the one end c of the second trace 05, such that the data signal is transmitted to the first data line 021 and the second data line 022 through the second line. In the case that the other end b of the first trace 04 and the other end d of the second trace 05 are in the high resistance state, the other end b of the first trace 04 and the second connection portion are break, and the other end d of the second trace 05 and the fourth connection portion are break. Referring to FIG. 5, in this case, only the second line is conducted in the crack detection circuit, such that the crack detection is performed through the second line.

In some embodiments, the first line 04 passes through a first side and a second side of the display region F, the second trace 05 passes through the second side and a third side of the display region F, the third trace 06 is disposed on a fourth side of the display region F. The first side is opposite to the third side, and the second side is opposite to the fourth side.

In some embodiments, as show in FIG. 3, the controller 03 is disposed on a lower side (that is, the fourth side) of the display region F. The third trace 06 is also disposed on the lower side of the display region F. and is disposed between the display region F and the controller 03. Two ends a and b of the first trace 04 are connected to a left half of the controller 03, and the first trace 04 surrounds all of a left side (that is, the first side) of the display region F and a part of an upper side (that is, the second side) of the display region F. Two ends c and d of the second trace 05 are connected to a right half of the controller 03, and the second trace 05 surrounds all of a right side (that is, the third side) of the display region F and a part of an upper side (that is, the second side) of the display region F.

In some embodiments, an orthogonal projection of the first trace 04 on a reference plane is overlapped with an orthogonal projection of the second trace 05 on the reference plane, and the reference plane is intersected with (such as, perpendicular to) a direction from the second side to the fourth side.

In some embodiments, as show in FIG. 3, a reference plane G is present above the base substrate 01. The reference plane is perpendicular to the base substrate 01, and perpendicular to the direction from the second side to the fourth side. The first trace 04 has a first projection on the reference plane G, the second trace 05 has a second projection on the reference plane G, and the first projection is overlapped with the second projection. It is acquired that the first trace 04 and the second trace 05 surround all of the upper side of the display region F, such that the crack detection is performed on all the upper side of the display region F.

In some embodiments, FIG. 6 is a schematic structural diagram of another display substrate according to some embodiments of the present disclosure. Referring to FIG. 6, on the basis of FIG. 3, the display substrate further includes a control line 07, a first switch assembly 081 corresponding to the first data line 021, and a second switch assembly 082 corresponding to the second data line 022.

The control line 07, the first switch assembly 081, and the second switch assembly 082 are disposed on the base substrate 01, the first data line 021 is connected to the first trace 04 through the first switch assembly 081, and the second data line 022 is connected to the second trace 05 through the second switch assembly 082. The control line 07 is connected to both the first switch assembly 081 and the second switch assembly 082, and two ends of the control line 07 are connected to the controller 03.

In some embodiments, as shown in FIG. 6, the display substrate includes three first data lines 021, and three first switch assemblies 081 in one-to-one correspondence to the three first data lines 021. Each first data line 021 is connected to the first trace 04 through the corresponding first switch assembly 081. The display substrate further includes three second data lines 022, and three second switch assemblies 082 in one-to-one correspondence to the three second data lines 022. Each second data line 022 is connected to the second trace 05 through the corresponding second switch assembly 082. The first switch assembly 081 and the second switch assembly 082 are disposed between the display region F and the third trace 06.

The controller 03 is configured to: in the first detection phase, provide a first signal to the control line 07, and the first signal is configured to control a switch assembly (including the first switch assembly 081 and the second switch assembly 082) connected to the control line 07 to be in a closed state; and in the second detection phase, provide a second signal to the control line 07, and the second signal is configured to control the switch assembly connected to the control line 07 to be in an open state. The switch assembly is closed in the first detection phase, such that an effect of the data line on the resistance in the first line is avoided. The switch assembly is opened in the second detection phase, such that the second line is conducted, and crack detection is performed on the second line.

In some embodiments, the plurality of data lines 02 further include at least one third data line 023 other than the at least one of the plurality of data lines connected to the second line y. The display substrate further includes at least one third switch assembly 083 in one-to-one correspondence to the at least one third data line 023. The third switch assembly 083 is disposed on the base substrate 01, each third data line 023 is connected to the third trace 06 through the corresponding third switch assembly 083, and the control line 07 is further connected to each third switch assembly 083.

The third data line 023 is connected to the third trace 06, one end of the third trace 06 is connected to the first connection portion e proximal to the one end a of the first trace 04 and the other end of the third trace 06 is connected to the third connection portion f proximal to the one end c of the second trace 05. Thus, in the second detection phase, the data signal provided by the controller 03 to the one end a of the first trace 04 is transmitted to the third data line 023 along the third trace 06 at the first connection portion e, the data signal provided by the controller 03 to the one end c of the second trace 05 is transmitted to the third data line 023 along the third trace 06 at the third connection portion f. It is acquired that, no matter whether the creak is present in the first side and the second side of the display region surrounded by the first trace 04, and the second side and the third side of the display region surrounded by the second trace 05 to result to break, the data signal provided by the controller 03 is transmitted to the third data line 023.

It is assumed that the pixel unit connected to the data line does not emit light in response to receiving the data signal at the high voltage and emits light in response to not receiving the data signal at the high voltage, and the data signal provided by the controller 03 to the one end a of the first trace 04 in the second detection phase is a high voltage signal (such as the data signal at 7V). In the case that the crack is present in the first side, the second side, or the third side of the display region, the pixel unit connected to the third data line 023 does not emit light in response to receiving the data signal at the high voltage provided by the controller 03, and the column of the pixel unit connected to the third data line 023 is a dark line. In addition, the pixel unit connected to the first data line 021 or the second data line 022 does not receive the data signal at the high voltage provided by the controller 03 and thus emits light, and the column of the pixel unit connected to the first data line 021 or the second data line 022 is a bright line. Thus, in the case that the crack is present in the first side, the second side, or the third side of the display region, a display difference of the bright line and the dark line is formed in the display region, and the display region shows bright and dark fringes. In the case that the crack is not present in the display region, each column of the pixel unit in the display region shows the dark line, and the entire display region is in a dark state. Thus, the user determines whether the crack is present in the display substrate by viewing whether the bright and dark fringes are present in the display region.

In some embodiments, as shown in FIG. 6, in addition to the three first data lines 021 and the three second data lines 022, the display region further includes nine third data lines 023. Furthermore, the first data lines 021, the second data lines 022, and the third data lines 023 are spaced apart uniformly with an arrangement sequence from left to right as: three third data lines 023, three first data lines 021, three third data lines 023, three second data lines 022, and three third data lines 023. Thus, in the case that the crack is present in the first side, the second side, or the third side of the display region, the pixel units connected to the nine third data lines 023 do not emit light, and the columns of the pixel units connected to the nine third data lines 023 are the dark lines. The pixel units connected to the three first data lines 021 or the three second data lines 022 emit light, and the columns of the pixel units connected to the three first data lines 021 or the three second data lines 022 are the bright lines. Therefore, a bright and dark difference between the columns of the pixel units connected to the three first data lines 021 or the three second data lines 022 and the columns of the pixel units connected to third data lines 023 is formed, such that an abnormal display is prone to be viewed.

In some embodiments, each of the first switch assembly 081, the second switch assembly 082, and the third switch assembly 083 is a thin-film transistor. The thin-film transistor is taken as the switch assembly, such that the switch assembly is simultaneously manufactured with the thin-film transistor in the pixel unit, and the manufacturing process is simplified.

In some embodiments, taking each of the first switch assembly 081, the second switch assembly 082, and the third switch assembly 083 being a p-type thin-film transistor as an example, the p-type thin-film transistor is closed at the high voltage signal, and is conducted at the low voltage signal. A voltage of the high voltage signal is higher than a voltage of the low voltage signal. Thus, in the first detection phase, the first signal provided by the controller 03 to two ends of the control line 07 is the high voltage signal, such that all switch assemblies are broken. In the second detection phase, the second signal provided by the controller 03 to two ends of the control line 07 is the low voltage signal, such that all switch assemblies are conducted. It is noted that the switch assemblies are n-type thin-film transistors. The n-type thin-film transistors are conducted at the high voltage signal, and are closed at the low voltage signal. The implementing processes are not repeated herein.

In some embodiments, the controller 03 is a driver IC. Because the driver IC includes a plurality of free ports, the process is simplified by taking the driver IC as the controller 03. The controller is not the driver IC, which is not limited in the embodiments of the present disclosure.

It is noted that the driver IC is connected to at least part of the data lines on the base substrate. In some embodiments, the driver IC is connected to each data line (not shown in the drawing). In some embodiments, the driver IC is connected to the first data line 081, the second data line 082, and the third data line 083, and is not connected to other data line (such as, dummy data line) than the first data line 081, the second data line 082, and the third data line 083. In some embodiments, the driver IC is connected to the data lines directly. In some embodiments, the driver IC is connected to the data lines through other circuit (such as a multiplexer (MUX)), which is not limited in the embodiments of the present disclosure.

In summary, a display substrate is provided in the embodiments of the present disclosure. The display substrate includes the crack detection circuit, and achieves a crack detection function. In addition, the crack detection circuit of the display substrate includes two different circuit, and thus supports two crack detection solutions.

In addition, two different traces share a part of the trace in the crack detection circuit, such that one trace includes two different line, and the one trace supports two crack detection solutions.

Furthermore, the crack detection circuit includes two second lines at different positions, such that the position of the crack is determined based on different data lines connected to different second lines.

A method for manufacturing the display substrate, applicable to manufacturing the display substrate in above embodiments, is provided in the embodiments of the present disclosure. FIG. 8 is a flowchart of a method for preparing the base substrate. As shown in FIG. 8, the method includes the following processes.

In S101, a base substrate is provided.

The base substrate includes a display region and a peripheral region surrounding the display region.

In S102, a plurality of data lines and a crack detection circuit are formed on the base substrate.

At least part of the plurality of data lines are disposed on the display region, and the crack detection circuit includes a first line and a second line. Two ends of the first line are connected to a controller, one end of the second line is connected to the controller, and the other end of the second line is connected to at least one of the plurality of data lines.

In summary, a method for manufacturing the display substrate is provided in the embodiments of the present disclosure. The display substrate manufactured by the method includes the crack detection circuit, such that the crack detection is performed on the display substrate. In addition, the crack detection circuit includes different circuit, and thus supports different crack detection solutions.

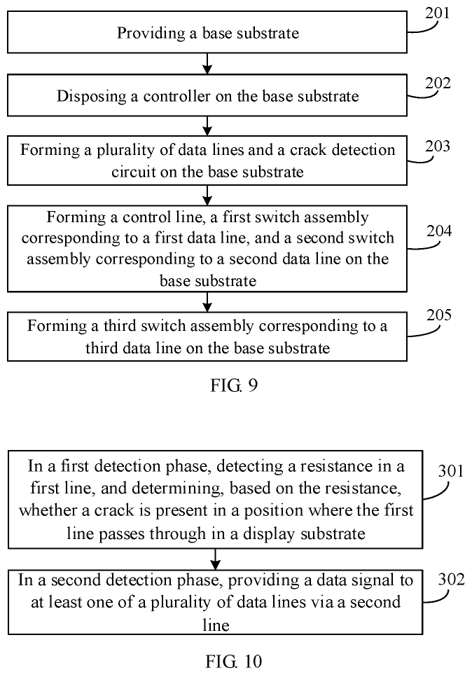

Another method for manufacturing the display substrate, applicable to manufacturing the display substrate in above embodiments, is provided in the embodiments of the present disclosure. FIG. 9 is a flowchart of a method for preparing the base substrate. As shown in FIG. 9, the method includes the following processes.

In S201, a base substrate is provided.

The base substrate includes a display region and a peripheral region surrounding the display region.

In S202, a controller is disposed on the base substrate.

In S203, a plurality of data lines and a crack detection circuit are formed on the base substrate.

At least part of the plurality of data lines are disposed on the display region, and the crack detection circuit includes a first trace, a second trace, and a third trace. Two ends of the first trace and two ends of the second trace are connected to the controller, and the first trace is connected to the second trace via the third trace.

The at least one of the plurality of data lines includes at least one first data line and at least one second data line. The first trace is connected to the at least one first data line, and the second trace is connected to the at least one second data line.

A first connection portion between the first trace and the third trace is proximal to one end of the first trace, and a second connection portion between the first trace and the at least one first data line is proximal to the other end of the first trace. A third connection portion between the second trace and the third trace is proximal to one end of the second trace, and a fourth connection portion between the second trace and the at least one second data line is proximal to the other end of the second trace.

It is noted that, the first trace, the second trace, and the third trace are disposed on the same layer, or are disposed on different layers. The first trace, the second trace, and the third trace are disposed on the same layer as the data line, or are disposed on different layers from the data line. The first trace, the second trace, and the third trace are disposed on the same layer as a gate line, or are disposed on different layers from the gate line, which is not limited in the present disclosure.

In some embodiments, the plurality of data lines further include at least one third data line other than the at least one of the plurality of data lines.

In S204, a control line, a first switch assembly corresponding to the first data line, and a second switch assembly corresponding to the second data line are formed on the base substrate.

The first data line is connected to the first trace through the corresponding first switch assembly, and the second data line is connected to the second trace through the corresponding second switch assembly. The control line is connected to both the first switch assembly and the second switch assembly, and two ends of the control line are connected to the controller.

It is noted that, the control line is disposed on the same layer as the first trace, the second trace, and the third trace, or is disposed on different layers from the first trace, the second trace, and the third trace. The control line is disposed on the same layer as the data line, or is disposed on different layers from the data line. The control line is disposed on the same layer as the gate line, or is disposed on different layers from the gate line, which is not limited in the present disclosure.

In S205, a third switch assembly corresponding to the third data line is formed on the base substrate.

The third data line is connected to the third trace through the corresponding third switch assembly, and the control line is further connected to the third switch assembly.

It is noted that, the third switch assembly is simultaneously formed with the second switch assembly and the first switch assembly.

It is noted that, the switch assembly (such as the first switch assembly, the second switch assembly and/or the third switch assembly) is formed at the same layer as the thin-film transistor in the pixel unit in the case that the switch assembly is the thin-film transistor.

In summary, a method for manufacturing the display substrate is provided in the embodiments of the present disclosure. The display substrate manufactured by the method includes the crack detection circuit, such that the crack detection is performed on the display substrate. In addition, the crack detection circuit includes different circuit, and thus supports different crack detection solutions.

A method for detecting a crack, applicable to the controller in the display substrate in above embodiments, is provided in the embodiments of the present disclosure. FIG. 10 is a flowchart of a method for detecting a crack according to some embodiments of the present disclosure. As shown in FIG. 10, the method includes the following processes.

In S301, in a first detection phase, a resistance in the first line is detected, and whether a crack is present in a position where the first line passes through in the display substrate is determined based on the resistance.

In S302, in a second detection phase, a data signal is provided to the at least one of the plurality of data lines via the second line.

Description of S301 is referred to the description of the function of the controller 03 achieved in the first detection phase in above embodiments, and description of S302 is referred to the description of the function of the controller 03 achieved in the second detection phase in above embodiments.

Above embodiments are described by taking S301 and S302 as an example. It is noted that, the method for detecting the crack in the embodiments only includes one of S301 and S302.

In summary, a method for detecting a crack is provided, and the method is applicable to the controller in the display substrate. In some embodiments, by detecting the resistance in the first line, whether the crack is present in the position where the first line passes through in the display substrate is determined based on the resistance. In some embodiments, the data signal is provided to the at least one of the plurality of data lines. In this case, the user determines whether the crack is present in the position where the second line passes through by viewing whether the pixel unit connected to the at least one of the plurality of data lines is displayed normally. Thus, the crack detection of the display substrate is achieved by the method.

In addition, different methods for detecting the crack are performed in different detection phases, such that the display substrate supports two crack detection solutions simultaneously.

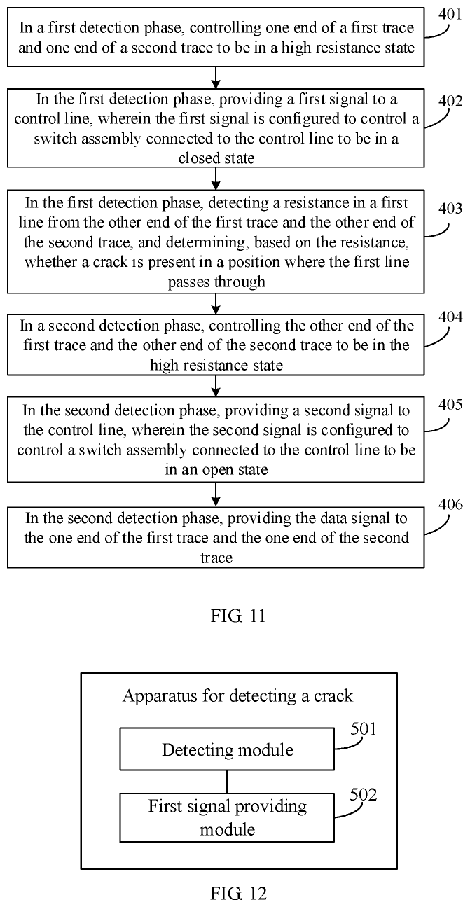

A method for detecting a crack, applicable to the controller in the display substrate in above embodiments, is provided in the embodiments of the present disclosure. FIG. 11 is a flowchart of a method for detecting a crack according to some embodiments of the present disclosure. As shown in FIG. 11, the method includes the following processes.

In S401, in a first detection phase, one end of the first trace and one end of the second trace are controlled to be in a high resistance state.

In S402, in the first detection phase, a first signal is provided to the control line, wherein the first signal is configured to control a switch assembly connected to the control line to be in a closed state.

In S403, in the first detection phase, a resistance in the first line is detected from the other end of the first trace and the other end of the second trace, and whether the crack is present in the position where the first line passes through is determined based on the resistance.

In S404, in a second detection phase, the other end of the first trace and the other end of the second trace are controlled to be in the high resistance state.

In S405, in the second detection phase, a second signal is provided to the control line, wherein the second signal is configured to control a switch assembly connected to the control line to be in an open state.

In S406, in the second detection phase, the data signal is provided to the one end of the first trace and the one end of the second trace.

Descriptions of S401 to S403 are referred to the description of the function of the controller 03 achieved in the first detection phase in above embodiments, and descriptions of S404 to S406 are referred to the description of the function of the controller 03 achieved in the second detection phase in above embodiments.

Above embodiments are described by taking S401 and S406 as an example. It is noted that, the method for detecting the crack in the embodiments only includes the detection method in the first detection phase (including S401 and S403), or only includes the detection method in the second detection phase (including S404 and S406).

In summary, a method for detecting a crack is provided, and the method is applicable to the controller in the display substrate. In some embodiments, by detecting the resistance in the first line, whether the crack is present in the position where the first line passes through in the display substrate is determined based on the resistance. In some embodiments, the data signal is provided to the at least one of the plurality of data lines. In this case, whether the crack is present in the position where the second line passes through is determined by viewing whether the pixel unit connected to the at least one of the plurality of data lines is displayed normally. Thus, the crack detection of the display substrate is achieved by the method.

In addition, different methods for detecting the cracks are performed in different detection phases, such that the display substrate supports two crack detection solutions simultaneously.

It is noted that, in some embodiments, the sequence of the steps in the method for detecting the crack in the embodiments of the present disclosure is adjusted appropriately. In some embodiments, the sequence of S401 and S402 is adjusted. The steps are added or deleted as required. In some embodiments, S402 is deleted. That is, the switch assembly is opened in the first detection phase, which does not affect detecting the resistance in the first line. Any method change made within the technical scope disclosed in the present disclosure by the person skilled in the art is included within the scope of protection of the present disclosure, and thus is not described in detail herein.

An apparatus for detecting a crack is provided in the present disclosure, and the apparatus is applicable to the controller in any display substrate in above embodiments. FIG. 12 is a schematic structural diagram of an apparatus for detecting a crack. As shown in FIG. 12, the apparatus for detecting the crack includes at least one of a detecting module 501 and a first signal providing module 502. FIG. 12 is shown by taking the apparatus for detecting the crack including the detecting module 501 and the first signal providing module 502 as an example.

The detecting module 501 is configured to, in a first detection phase, detecting a resistance in the first line, and determine, based on the resistance, whether a crack is present in a position where the first line passes through in the display substrate.

The first signal providing module 502 is configured to, in a second detection phase, providing a data signal to the at least one of the plurality of data lines via the second line.

In some embodiments, in the case that the apparatus for detecting the crack includes the detecting module, the apparatus for detecting the crack further includes: a first control module (not shown in FIG. 12), configured to control one end of the first trace and one end of the second trace to be in a high resistance state in the first detection phase; and the detecting module is configured to detect a resistance in the first line from the other end of the first trace and the other end of the second trace.

In the case that the apparatus for detecting the crack include the first signal providing module, the apparatus for detecting the crack further includes: a second control module (not shown in FIG. 12), configured to control the other end of the first trace and the other end of the second trace to be in the high resistance state in the second detection phase: the first signal providing module is configured to provide a data signal to the one end of the first trace and the one end of the second trace.

In some embodiments, in the case that the apparatus for detecting the crack includes the detecting module, the apparatus for detecting the crack further includes: a second signal providing module (not shown in FIG. 12), configured to provide a first signal to the control line in the first detection phase. The first signal is configured to control a switch assembly connected to the control line to be in a closed state.

In the case that the apparatus for detecting the crack includes the first signal providing module, the apparatus for detecting the crack further includes: a third signal providing module (not shown in FIG. 12), configured to provide a second signal to the control line in the second detection phase. The second signal is configured to control the switch assembly connected to the control line to be in an open state.

It is clear for those skilled in the art that to understand that, above specific operation processes of the apparatus and the module are referred to corresponding process in above method embodiments for convenient and simply description, which is not repeated herein.

A chip is provided in the embodiments of the present disclosure. The chip is applicable to a controller and includes a programmable logic circuit and/or program instructions. The chip, when running, is caused to perform any method for detecting the crack according to the above embodiments.

A computer-readable storage medium is provided in the embodiments of the present disclosure. The computer-readable storage medium stores instructions. The computer-readable storage medium, when running on a processing assembly, causes the processing assembly perform the processes performed by the controller or the chip in above embodiments.

A computer program product including instructions is provided. The computer program product, when running on a computer, causes the computer to perform the method for detecting the crack according to the above method embodiments.

The embodiments of the present disclosure provide a display device, and the display device includes any display substrate according to above embodiments.

In some embodiments, the display device is any products or parts with a display function, such as a display panel, a liquid crystal display (LCD), an organic light-emitting diode (OLED) display device, a micro light emitting diode (Micro LED) display device, a quantum dot light emitting diode (QLED) display device, electronic paper, a mobile phone, a tablet computer, a television, a display, a notebook computer, a digital photo frame, a navigator, and the like.

In the present disclosure, the terms “first” and “second” are used to descriptive purposes, and are not construed to indicate or imply relative importance. Unless expressly limited otherwise, the term “at least one” refers to one or more, and the term “a plurality of” refers to two or more.

It is noted that the term “and/or” in the context indicates three relationships. In some embodiments, A and/or B indicates: A alone, A and B, and B clone. The symbol “/” generally indicates that the associated objects are in an “or” relationship.

Described above are example embodiments of the present disclosure, and are not intended to limit the present disclosure. Any modifications, equivalent replacements, improvements and the like made within the spirit and principles of the present disclosure are included within the scope of protection of the present disclosure.

1. A display substrate, comprising: a base substrate, a plurality of data lines, and a crack detection circuit that are disposed on the base substrate; wherein
the base substrate comprises a display region and a peripheral region surrounding the display region, at least part of the plurality of data lines are disposed on the display region, and the crack detection circuit comprises a first line and a second line;
wherein two ends of the first line are connected to a controller, one end of the second line is connected to the controller, and the other end of the second line is connected to at least one of the plurality of data lines.

2. The display substrate according to claim 1, wherein
the crack detection circuit comprises a first trace, a second trace, and a third trace, wherein two ends of the first trace and two ends of the second trace are connected to the controller, and the first trace is connected to the second trace via the third trace;
the at least one of the plurality of data lines comprises at least one first data line and at least one second data line, wherein the first trace is connected to the at least one first data line, and the second trace is connected to the at least one second data line;
wherein a first connection portion between the first trace and the third trace is proximal to one end of the first trace, and a second connection portion between the first trace and the at least one first data line is proximal to the other end of the first trace; and a third connection portion between the second trace and the third trace is proximal to one end of the second trace, and a fourth connection portion between the second trace and the at least one second data line is proximal to the other end of the second trace;
the first line successively passes through the other end of the first trace, the first connection portion, the third trace, the third connection portion, and the other end of the second trace; and
the crack detection circuit comprises two second lines, wherein one of the two second lines successively passes through the one end of the first trace, the first connection portion, and the second connection portion, and the other of the two second lines successively passes through the one end of the second trace, the third connection portion, and the fourth connection portion.

3. The display substrate according to claim 1, further comprising: the controller disposed on the peripheral region of the base substrate; wherein
the at least one of the plurality of data lines extends from the display region to the peripheral region and is connected to the controller; and
the controller is configured to:
in a first detection phase, detect a resistance in the first line, and determining, based on the resistance, whether a crack is present in a position where the first line passes through in the display substrate; and/or
in a second detection phase, provide a data signal to the at least one of the plurality of data lines via the second line.

4. The display substrate according to claim 2, further comprising: the controller disposed on the peripheral region of the base substrate; wherein
the at least one of the plurality of data lines extends from the display region to the peripheral region and is connected to the controller; and
the controller is configured to:
in the first detection phase, control the one end of the first trace and the one end of the second trace to be in a high resistance state, detect a resistance in the first line from the other end of the first trace and the other end of the second trace, and determine, based on the resistance, whether a crack is present in a position where the first line passes through in the display substrate.

5. The display substrate according to claim 2, further comprising: the controller disposed on the peripheral region of the base substrate; wherein
the at least one of the plurality of data lines extends from the display region to the peripheral region and is connected to the controller; and
the controller is configured to:
in the second detection phase, control the other end of the first trace and the other end of the second trace to be in a high resistance state, and provide a data signal to the one end of the first trace and the one end of the second trace.

6. The display substrate according to claim 2, wherein the first trace passes through a first side and a second side of the display region, the second trace passes through the second side and a third side of the display region, and the third trace is disposed on a fourth side of the display region, wherein the first side is opposite to the third side, and the second side is opposite to the fourth side.

7. The display substrate according to claim 6, wherein an orthogonal projection of the first trace on a reference plane is overlapped with an orthogonal projection of the second trace on the reference plane, wherein the reference plane is intersected with a direction from the second side to the fourth side.

8. The display substrate according to claim 2, further comprising: a control line, a first switch assembly corresponding to the first data line, and a second switch assembly corresponding to the second data line; wherein
the control line, the first switch assembly, and the second switch assembly are disposed on the base substrate, the first data line is connected to the first trace through the corresponding first switch assembly, and the second data line is connected to the second trace through the corresponding second switch assembly; and the control line is connected to both the first switch assembly and the second switch assembly, and two ends of the control line are connected to the controller; and
the controller is configured to:
in the first detection phase, provide a first signal to the control line, wherein the first signal is configured to control a switch assembly connected to the control line to be in a closed state;
in the second detection phase, provide a second signal to the control line, wherein the second signal is configured to control the switch assembly connected to the control line to be in an open state.

9. The display substrate according to claim 8, wherein
the plurality of data lines further comprise: at least one third data line other than the at least one of the plurality of data lines, wherein at least part of the at least one third data line is disposed on the display region; and
the display substrate further comprises: a third switch assembly corresponding to the third data line, wherein the third switch assembly is disposed on the base substrate.

10. The display substrate according to claim 9, wherein each of the first switch assembly, the second switch assembly, and the third switch assembly is a thin-film transistor.

11. The display substrate according to claim 1, wherein the controller is a driver integrated circuit IC.

12. A method for detecting a crack, applicable to a controller connected to a crack detection circuit in a display substrate, wherein
the display substrate comprises: a base substrate, a plurality of data lines, and the crack detection circuit that are disposed on the base substrate; wherein
the base substrate comprises a display region and a peripheral region surrounding the display region, at least part of the plurality of data lines are disposed on the display region, and the crack detection circuit comprises a first line and a second line;
wherein two ends of the first line are connected to the controller, one end of the second line is connected to the controller, and the other end of the second line is connected to at least one of the plurality of data lines;
and the method comprises: at least one of detection methods in a first detection phase and a second detection phase; wherein
a detection method in the first detection phase comprises: detecting a resistance in the first line, and determining, based on the resistance, whether a crack is present in a position where the first line passes through in the display substrate; and
a detection method in the second detection phase comprises: providing a data signal to the at least one of the plurality of data lines via the second line.

13. The method according to claim 12, wherein
the crack detection circuit comprises: a first trace, a second trace, and a third trace;
the detection method in the first detection phase further comprises: controlling one end of the first trace and one end of the second trace to be in a high resistance state;
the detection method in the second detection phase further comprises: controlling the other end of the first trace and the other end of the second trace to be in the high resistance state;
detecting the resistance in the first line comprises: detecting a resistance in the first line from the other end of the first trace and the other end of the second trace; and
providing the data signal to the at least one of the plurality of data lines via the second line comprises: providing a data signal to the one end of the first trace and the one end of the second trace.

14. The method according to claim 13, wherein
the display substrate comprises: a control line, at least one first switch assembly, and at least one second switch assembly;
the detection method in the first detection phase further comprises: providing a first signal to the control line, wherein the first signal is configured to control a switch assembly connected to the control line to be in a closed state; and
the detection method in the second detection phase further comprises: providing a second signal to the control line, wherein the second signal is configured to control the switch assembly connected to the control line to be in an open state.

15. A display device, comprising: a display substrate; wherein
the display substrate comprises: a base substrate, a plurality of data lines, and a crack detection circuit that are disposed on the base substrate; wherein
the base substrate comprises a display region and a peripheral region surrounding the display region, at least part of the plurality of data lines are disposed on the display region, and the crack detection circuit comprises a first line and a second line;
wherein two ends of the first line are connected to a controller, one end of the second line is connected to the controller, and the other end of the second line is connected to at least one of the plurality of data lines.

16. The display device according to claim 15, wherein
the crack detection circuit comprises a first trace, a second trace, and a third trace, wherein two ends of the first trace and two ends of the second trace are connected to the controller, and the first trace is connected to the second trace via the third trace;
the at least one of the plurality of data lines comprises at least one first data line and at least one second data line, wherein the first trace is connected to the at least one first data line, and the second trace is connected to the at least one second data line;
wherein a first connection portion between the first trace and the third trace is proximal to one end of the first trace, and a second connection portion between the first trace and the at least one first data line is proximal to the other end of the first trace; and a third connection portion between the second trace and the third trace is proximal to one end of the second trace, and a fourth connection portion between the second trace and the at least one second data line is proximal to the other end of the second trace;
the first line successively passes through the other end of the first trace, the first connection portion, the third trace, the third connection portion, and the other end of the second trace; and
the crack detection circuit comprises two second lines, wherein one of the two second lines successively passes through the one end of the first trace, the first connection portion, and the second connection portion, and the other of the two second lines successively passes through the one end of the second trace, the third connection portion, and the fourth connection portion.

17. The display device according to claim 15, further comprising: the controller disposed on the peripheral region of the base substrate; wherein
the at least one of the plurality of data lines extends from the display region to the peripheral region and is connected to the controller; and
the controller is configured to:
in a first detection phase, detect a resistance in the first line, and determining, based on the resistance, whether a crack is present in a position where the first line passes through in the display substrate; and/or
in a second detection phase, provide a data signal to the at least one of the plurality of data lines via the second line.

18. The display device according to claim 16, further comprising: the controller disposed on the peripheral region of the base substrate; wherein
the at least one of the plurality of data lines extends from the display region to the peripheral region and is connected to the controller; and
the controller is configured to:
in the first detection phase, control the one end of the first trace and the one end of the second trace to be in a high resistance state, detect a resistance in the first line from the other end of the first trace and the other end of the second trace, and determine, based on the resistance, whether a crack is present in a position where the first line passes through in the display substrate.

19. The display device according to claim 16, further comprising: the controller disposed on the peripheral region of the base substrate; wherein
the at least one of the plurality of data lines extends from the display region to the peripheral region and is connected to the controller; and
the controller is configured to:
in the second detection phase, control the other end of the first trace and the other end of the second trace to be in a high resistance state, and provide a data signal to the one end of the first trace and the one end of the second trace.

20. The display device according to claim 16, wherein the first trace passes through a first side and a second side of the display region, the second trace passes through the second side and a third side of the display region, and the third trace is disposed on a fourth side of the display region, wherein the first side is opposite to the third side, and the second side is opposite to the fourth side.
